(19) United States
(12) Patent Application Publication
(10) Pub. No.: US 2023/0156866 A1
(43) Pub. Date: May 18, 2023

(54) LIQUID COOLING HEAT DISSIPATION SUBSTRATE STRUCTURE WITH PARTIAL COMPRESSION REINFORCEMENT

(71) Applicant: AMULAIRE THERMAL TECHNOLOGY, INC., New Taipei City (TW)

(72) Inventors: CHENG-SHU PENG, New Taipei City (TW); YEN-CHUN LIN, New Taipei City (TW)

(21) Appl. No.: 17/527,098

(22) Filed: Nov. 15, 2021

(51) Int. Cl. H05B 3/02; H05K 7/20

(52) U.S. Cl. CPC H05B 3/02; H05K 7/2039

(57) ABSTRACT

A liquid cooling heat dissipation substrate structure with partial compression reinforcement is provided. The liquid cooling heat dissipation substrate structure with partial compression reinforcement includes a heat dissipation base that integrally has a heat dissipation main structure and a compression reinforcement structure. The heat dissipation main structure and the compression reinforcement structure are formed through different processes. The heat dissipation main structure and the compression reinforcement structure have different metallographic microstructures. Crystallites of the metallographic microstructure of the heat dissipation main structure are not all arranged in one specific direction, and crystallites of the metallographic microstructure of the compression reinforcement structure are stacked and arranged in a direction that is perpendicular to a compression direction.

### FIELD OF THE DISCLOSURE

The present disclosure relates to a heat dissipation substrate structure, and more particularly to a liquid cooling heat dissipation substrate structure with partial compression reinforcement.

### BACKGROUND OF THE DISCLOSURE

Due to the heat dissipation requirements of high-power heating elements, conventionally, main bodies of heat sinks of the high-power heating elements are mostly made of copper. However, regardless of whether the heat sink is formed by metal diffusion bonding or metal sintering, the material strength thereof is inevitably decreased, thereby leading to a significant decrease in service life of the product.

### SUMMARY OF THE DISCLOSURE

In response to the above-referenced technical inadequacies, the present disclosure provides a liquid cooling heat dissipation substrate structure with partial compression reinforcement.

In one aspect, the present disclosure provides a liquid cooling heat dissipation substrate structure with partial compression reinforcement, and the liquid cooling heat dissipation substrate structure includes a heat dissipation base that integrally has a heat dissipation main structure and a compression reinforcement structure, the heat dissipation main structure and the compression reinforcement structure being formed through different processes, and the heat dissipation main structure and the compression reinforcement structure having different metallographic microstructures. Crystallites of the metallographic microstructure of the heat dissipation main structure are not all arranged in one specific direction, and crystallites of the metallographic microstructure of the compression reinforcement structure are stacked and arranged in a direction that is perpendicular to a compression direction.

In a preferred embodiment, the heat dissipation base is an integral structure formed through a metal diffusion bonding process, and the compression reinforcement structure is formed by performing compression reinforcement on portions of the heat dissipation base through a pressure application process.

In an exemplary embodiment, the compression reinforcement structure is a structure formed on the heat dissipation base through at least one of a stamping process, a forging process, and a press forging process.

In an exemplary embodiment, the heat dissipation base is an integral structure formed through a metal powder sintering process, and the compression reinforcement structure is formed by performing compression reinforcement on portions of the heat dissipation base through a pressure application process.

In an exemplary embodiment, the heat dissipation base is formed from one of copper and a copper alloy.

In an exemplary embodiment, a fin structure is integrally formed on a surface of the heat dissipation base, and a plurality of reinforcement portions of the compression reinforcement structure and a plurality of fins of the fin structure are arranged alternately and in parallel to each other.

In an exemplary embodiment, a fin structure is integrally formed on a surface of the heat dissipation base, and a plurality of reinforcement portions of the compression reinforcement structure are in alternate and parallel arrangement with a plurality of pin-fins of the fin structure that are arranged in rows.

In an exemplary embodiment, a fin structure is integrally formed on a surface of the heat dissipation base, and a plurality of reinforcement portions of the compression reinforcement structure are alternately arranged between a plurality of pin-fins of the fin structure in perpendicular and parallel manners.

In an exemplary embodiment, the compression reinforcement structure is at least one of an indentation, a depression, a patterned indentation and a patterned depression.

Therefore, in the liquid cooling heat dissipation substrate structure with partial compression reinforcement provided by the present disclosure, by virtue of “the heat dissipation base integrally having a heat dissipation main structure and a compression reinforcement structure,” “the heat dissipation main structure and the compression reinforcement structure being formed through different processes,” “the heat dissipation main structure and the compression reinforcement structure having different metallographic microstructures,” and “crystallites of the metallographic microstructure of the heat dissipation main structure being not all arranged in one specific direction, and crystallites of the metallographic microstructure of the compression reinforcement structure being stacked and arranged in a direction that is perpendicular to a compression direction,” a structural strength of the heat dissipation base is effectively increased, thereby strengthening an overall structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic top view of a liquid cooling heat dissipation substrate structure with partial compression reinforcement according to a first embodiment of the present disclosure;

FIG. 2 is a cross-sectional view along line II-II of FIG. 1;

FIG. 3 is a schematic top view of a liquid cooling heat dissipation substrate structure with partial compression reinforcement according to a second embodiment of the present disclosure;

FIG. 4 is a schematic top view of a liquid cooling heat dissipation substrate structure with partial compression reinforcement according to a third embodiment of the present disclosure; and

FIG. 5 is a schematic top view of a liquid cooling heat dissipation substrate structure with partial compression reinforcement according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way.

Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

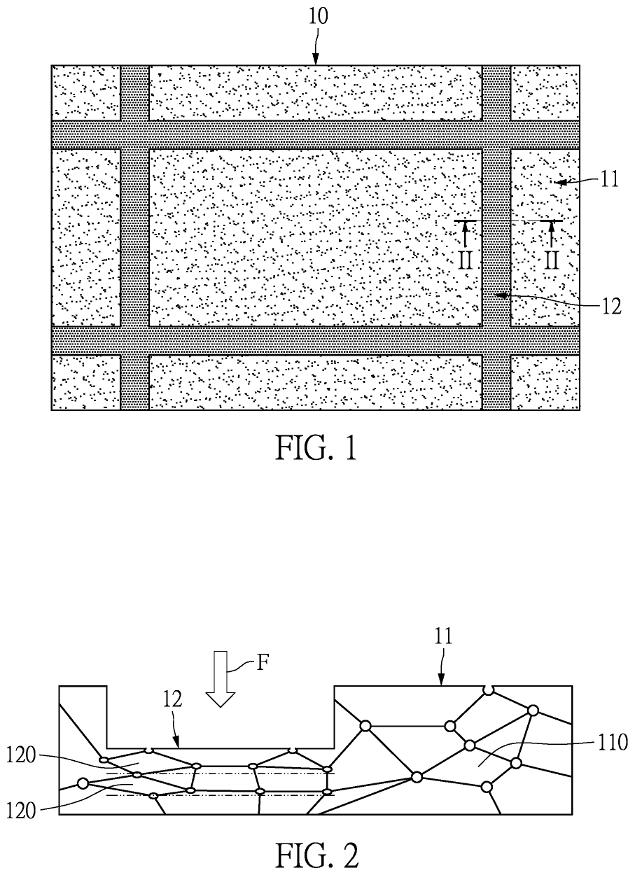

Reference is made to FIG. 1 and FIG. 2, which show an embodiment of the present disclosure. A liquid cooling heat dissipation substrate structure with partial compression reinforcement is provided in this embodiment of the present disclosure for contacting heat emitting elements. As shown in FIG. 1 and FIG. 2, the liquid cooling heat dissipation substrate structure with partial compression reinforcement provided in the present disclosure can include a heat dissipation base 10 that integrally has a heat dissipation main structure 11 and a compression reinforcement structure 12.

Furthermore, the heat dissipation base 10 of this embodiment is an integral structure formed through a metal diffusion bonding process, and then the compression reinforcement structure 12 is formed by performing compression reinforcement on portions of the heat dissipation base 10 through a pressure application process (e.g., a stamping process, a forging process or a press forging process), such that the heat dissipation main structure 11 and the compression reinforcement structure 12 of the heat dissipation base 10 are formed through different processes.

The heat dissipation main structure 11 and the compression reinforcement structure 12 have different metallographic microstructures. As shown in FIG. 2, crystallites 110 of the metallographic microstructure of the heat dissipation main structure 11 are not all arranged in one specific direction, that is, the crystallites 110 of the metallographic microstructure of the heat dissipation main structure 11 are in an irregular or a random arrangement, and crystallites 120 of the metallographic microstructure of the compression reinforcement structure 12 are stacked and arranged in a direction that is perpendicular to a compression direction F, that is, the crystallites 120 of the metallographic microstructure of the compression reinforcement structure 12 are stacked and arranged in a formation perpendicular to the compression direction F. Accordingly, a structural strength of a heat dissipation substrate is effectively increased, thereby strengthening an overall structure of the heat dissipation substrate.

Furthermore, the heat dissipation base 10 of this embodiment can be an integral structure formed through a metal powder sintering process, and can be a porous copper heat dissipation base formed by heating and sintering of a copper or a copper alloy powder. Afterwards, the compression reinforcement structure 12 is formed by performing compression reinforcement on specific portions of the heat dissipation base 10 through a pressure application process, such that the heat dissipation main structure 11 and the compression reinforcement structure 12 of the heat dissipation base 10 are formed through different processes. In addition, the heat dissipation base 10 can be a liquid cooling porous heat sink being immersed in a two-phase coolant and having a porosity greater than 5%, so as to improve an overall heat dissipation effect. Furthermore, the compression reinforcement structure 12 can be an indentation, a depression, a patterned indentation, or a patterned depression.

### Second Embodiment

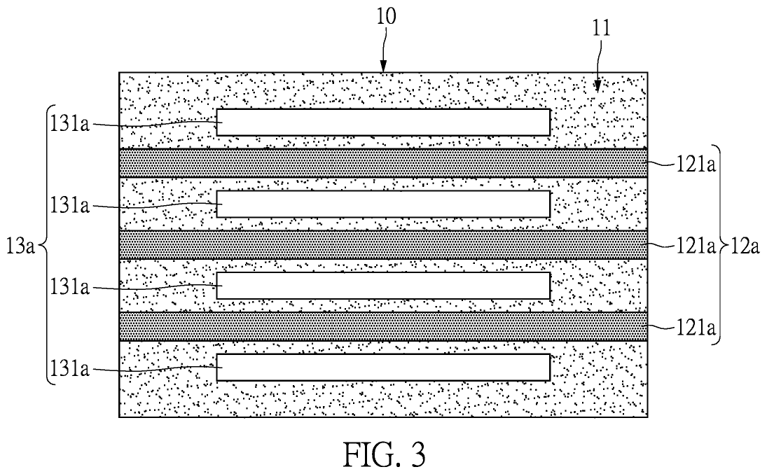

Reference is made to FIG. 3, which is one embodiment of the present disclosure. As shown in a schematic top view of FIG. 3, the liquid cooling heat dissipation substrate structure with partial compression reinforcement provided in the present disclosure can include a heat dissipation base 10 that integrally has a heat dissipation main structure 11 and a compression reinforcement structure 12a.

In addition, a fin structure 13a is integrally formed on a surface of the heat dissipation base 10, and a plurality of reinforcement portions 121a of the compression reinforcement structure 12a and a plurality of plate-shaped fins 131a of the fin structure 13a are arranged alternately and in parallel to each other, effectively increasing the heat dissipation effect and structural strength of the heat dissipation substrate.

### Third Embodiment

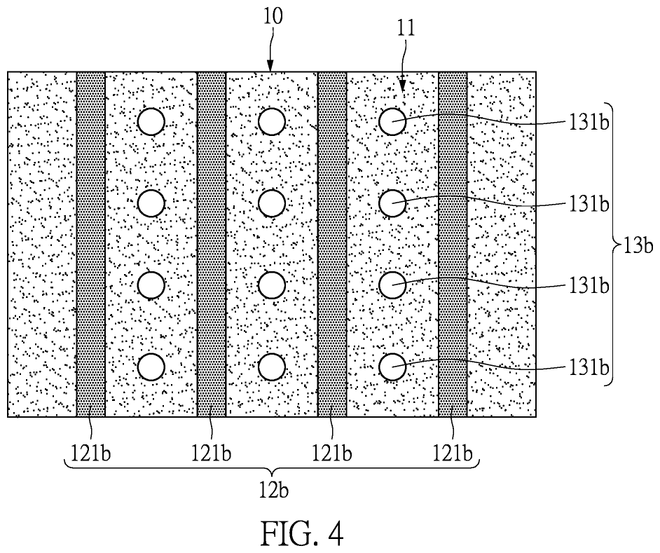

Reference is made to FIG. 4, which is one embodiment of the present disclosure. As shown in a schematic top view of FIG. 4, the liquid cooling heat dissipation substrate structure with partial compression reinforcement provided in the present disclosure can include a heat dissipation base 10 that integrally has a heat dissipation main structure 11 and a compression reinforcement structure 12b.

In addition, a fin structure 13b is integrally formed on a surface of the heat dissipation base 10, and a plurality of reinforcement portions 121b of the compression reinforcement structure 12b are in alternate and parallel arrangement with a plurality of pin-fins 131b of the fin structure 13b that are arranged in rows, effectively increasing the heat dissipation effect and structural strength of the heat dissipation substrate.

### Fourth Embodiment

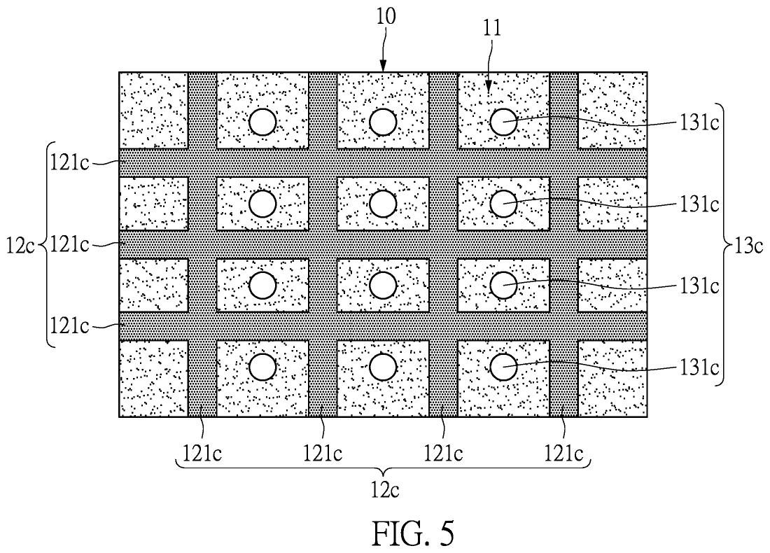

Reference is made to FIG. 5, which is one embodiment of the present disclosure. As shown in a schematic top view of FIG. 5, the liquid cooling heat dissipation substrate structure with partial compression reinforcement provided in the present disclosure can include a heat dissipation base 10 that integrally has a heat dissipation main structure 11 and a compression reinforcement structure 12c.

In addition, a fin structure 13c is integrally formed on a surface of the heat dissipation base 10, and a plurality of reinforcement portions 121c of the compression reinforcement structure 12c are alternately arranged between a plurality of pin-fins 131c of the fin structure 13c in perpendicular and parallel manners, effectively increasing the heat dissipation effect and structural strength of the heat dissipation substrate.

### Beneficial Effects of the Embodiments

In conclusion, in the liquid cooling heat dissipation substrate structure with partial compression reinforcement provided by the present disclosure, by virtue of “the heat dissipation base integrally having a heat dissipation main structure and a compression reinforcement structure,” “the heat dissipation main structure and the compression reinforcement structure being formed through different processes,” “the heat dissipation main structure and the compression reinforcement structure having different metallographic microstructures,” and “crystallites of the metallographic microstructure of the heat dissipation main structure being not all arranged in one specific direction, and crystallites of the metallographic microstructure of the compression reinforcement structure being stacked and arranged in a direction that is perpendicular to a compression direction,” a structural strength of the heat dissipation base is effectively increased, thereby strengthening an overall structure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A liquid cooling heat dissipation substrate structure with partial compression reinforcement, comprising:
a heat dissipation base integrally having a heat dissipation main structure and a compression reinforcement structure, the heat dissipation main structure and the compression reinforcement structure being formed through different processes, and the heat dissipation main structure and the compression reinforcement structure having different metallographic microstructures; wherein crystallites of the metallographic microstructure of the heat dissipation main structure are not all arranged in one specific direction, and crystallites of the metallographic microstructure of the compression reinforcement structure are stacked and arranged in a direction that is perpendicular to a compression direction.

2. The liquid cooling heat dissipation substrate structure according to claim 1, wherein the heat dissipation base is an integral structure formed through a metal diffusion bonding process, and the compression reinforcement structure is formed by performing compression reinforcement on portions of the heat dissipation base through a pressure application process.

3. The liquid cooling heat dissipation substrate structure according to claim 2, wherein the compression reinforcement structure is a structure formed on the heat dissipation base through at least one of a stamping process, a forging process, and a press forging process.

4. The liquid cooling heat dissipation substrate structure according to claim 1, wherein the heat dissipation base is an integral structure formed through a metal powder sintering process, and the compression reinforcement structure is formed by performing compression reinforcement on portions of the heat dissipation base through a pressure application process.

5. The liquid cooling heat dissipation substrate structure according to claim 4, wherein the compression reinforcement structure is a structure formed on the heat dissipation base through at least one of a stamping process, a forging process, and a press forging process.

6. The liquid cooling heat dissipation substrate structure according to claim 1, wherein the heat dissipation base is formed from one of copper and a copper alloy.

7. The liquid cooling heat dissipation substrate structure according to claim 1, wherein a fin structure is integrally formed on a surface of the heat dissipation base, and a plurality of reinforcement portions of the compression reinforcement structure and a plurality of fins of the fin structure are arranged alternately and in parallel to each other.

8. The liquid cooling heat dissipation substrate structure according to claim 1, wherein a fin structure is integrally formed on a surface of the heat dissipation base, and a plurality of reinforcement portions of the compression reinforcement structure are in alternate and parallel arrangement with a plurality of pin-fins of the fin structure that are arranged in rows.

9. The liquid cooling heat dissipation substrate structure according to claim 1, wherein a fin structure is integrally formed on a surface of the heat dissipation base, and a plurality of reinforcement portions of the compression reinforcement structure are alternately arranged between a plurality of pin-fins of the fin structure in perpendicular and parallel manners.

10. The liquid cooling heat dissipation substrate structure according to claim 1, wherein the compression reinforcement structure is at least one of an indentation, a depression, a patterned indentation and a patterned depression.
